(19) United States
(12) Patent Application Publication
(10) Pub. No.: US 2014/0261628 A1
(43) Pub. Date: Sep. 18, 2014

(54) HIGH EFFICIENCY SOLAR RECEIVERS INCLUDING STACKED SOLAR CELLS FOR CONCENTRATOR PHOTOVOLTAICS

(71) Applicant: Semprius, Inc., Durham, NC (US)

(72) Inventors: Matthew Meitl, Durham, NC (US); Etienne Menard, Limoges (FR); Christopher Bower, Raleigh, NC (US)

(73) Assignee: Semprius, Inc., Durham, NC (US)

(21) Appl. No.: 14/211,708

(22) Filed: Mar. 14, 2014

Related U.S. Application Data
(60) Provisional application No. 61/782,983, filed on Mar. 14, 2013.

(51) Int. Cl. H01L 31/052; H01L 31/18

(52) U.S. Cl. CPC H01L 31/0524; H01L 31/1876
USPC 136/246; 136/244; 438/67

(57) ABSTRACT

A solar receiver includes at least two electrically independent photovoltaic cells which are stacked. An inter-cell interface between the photovoltaic cells includes a multi-layer dielectric stack. The multi-layer dielectric stack includes at least two dielectric layers having different refractive indices. Related devices and fabrication methods are also discussed.

### CLAIM OF PRIORITY

This application claims priority to U.S. provisional patent application No. 61/782,983 entitled “HIGH EFFICIENCY SOLAR RECEIVERS INCLUDING STACKED SOLAR CELLS FOR CONCENTRATOR PHOTOVOLTAICS” filed on Mar. 14, 2013, the disclosure of which is incorporated by reference herein in its entirety.

### FIELD

The present invention relates to solar photovoltaic power generation, and more particularly, to concentrated photovoltaic (CPV) power generation.

### BACKGROUND

Concentrator photovoltaics (CPV) is an increasingly promising technology for renewable electricity generation in sunny environments. CPV uses relatively inexpensive, efficient optics to concentrate sunlight onto solar cells, thereby reducing the cost requirements of the semiconductor material and enabling economic use of efficient cells, for example multi junction solar cells. This high efficiency at reduced costs, in combination with other aspects, makes CPV among the more economical renewable solar electricity technologies in sunny climates and geographic regions.

Concentrator photovoltaic solar cell systems may use lenses or mirrors to focus a relatively large area of sunlight onto a relatively small solar cell. The solar cell can convert the focused sunlight into electrical power. By optically concentrating the sunlight into a smaller area, fewer and smaller solar cells with greater conversion performance can be used to create more efficient photovoltaic systems at lower cost.

For example, CPV module designs that use small solar cells (for example, cells that are smaller than about 4 mm²) may benefit significantly because of the ease of energy extraction from such cells. The superior energy extraction characteristics can apply to both usable electrical energy and waste heat, potentially allowing a better performance-to-cost ratio than CPV module designs that use larger cells. To increase or maximize the performance of concentrated photovoltaic systems, CPV systems can be mounted on a tracking system that aligns the CPV system optics with a light source (typically the sun) such that the incident light is substantially parallel to an optical axis of the concentrating optical elements, to focus the incident light onto the photovoltaic elements.

Some designs and processes for making micro-concentrator solar modules are described in U.S. Patent Application Publication No. 2008/0121269. Also, some methods for making advanced concentrator photovoltaic modules, receivers, and sub-receivers are described in U.S. Patent Application Publication No. 2010/0236603.

### SUMMARY

According to some embodiments of the present invention, a solar receiver includes at least two electrically independent photovoltaic cells which are stacked (for example, vertically).

In some embodiments, an inter-cell interface between the photovoltaic cells includes a multi-layer dielectric stack. The multi-layer dielectric stack includes at least two dielectric layers having different refractive indices, and is configured to reduce Fabry-Perot cavity light loss and/or provide high dielectric strength between the electrically isolated photovoltaic cells.

In some embodiments, one or more of the photovoltaic cells (also referred to as subcells of the solar receiver) may include at least two conductive terminals, such that the solar receiver is a multi-terminal device.

In some embodiments, the photovoltaic cells may be single-junction or multi-junction photovoltaic cells.

In some embodiments, the photovoltaic cells may be grown or otherwise formed to have different lattice constants, which may allow for different bandgap combinations and/or interfaces within the solar receiver.

In some embodiments, the solar receiver may include two stacked photovoltaic cells, and the solar receiver may be a four terminal device.

In some embodiments, the invention may provide methods and structures for producing an interface between the stacked cells that has high optical transparency in a wavelength range of interest.

In some embodiments, the invention may provide methods and structures for extraction of the generated photocurrent, for example, from the lowest subcell in the stack.

In some embodiments, the invention may provide methods and structures that provide a surface-mountable solar receiver.

Other methods and/or devices according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

Aspects of the present disclosure are illustrated by way of example and are not limited by the accompanying figures with like references indicating like elements.

FIG. 1 is a block diagram of a solar receiver including vertically stacked electrically independent subcells according to some embodiments of the present invention.

FIG. 2 illustrates a low optical loss interface according to some embodiments of the present invention in greater detail.

FIG. 3 is a graph illustrating optical transmission through an optical interface provided by a multi-layer dielectric stack according to some embodiments of the present invention.

FIGS. 4A-4D illustrate fabrication steps that may be used for forming solar receivers including vertically stacked subcells according to embodiments of the present invention using one or more transfer-printing processes.

FIG. 5 illustrates a four-terminal solar receiver according to some embodiments of the present invention.

FIG. 6 illustrates a four-terminal solar receiver according to further embodiments of the present invention.

FIG. 7 illustrates a four-terminal solar receiver according to some embodiments of the present invention.

FIG. 8 illustrates a two-terminal stacked solar receiver according to some embodiments of the present invention.

FIG. 9 illustrates a surface-mountable four-terminal solar receiver according to some embodiments of the present invention.

FIGS. 10A-10B illustrate front and back views, respectively, of a surface-mountable four-terminal solar receiver according to some embodiments of the present invention.

FIG. 11 illustrates a voltage matching network that may be used with solar receivers according to some embodiments of the present invention.

FIG. 12 illustrates a current matching network that may be used with solar receivers according to some embodiments of the present invention.

FIG. 13 illustrates a solar receiver including a two-subcell stack according to some embodiments of the present invention.

FIG. 14 is an optical microscope image illustrating a solar receiver according to some embodiments of the present invention.

### DETAILED DESCRIPTION

Embodiments of the present invention provide solar receivers, which may be used, for example, in concentrator photovoltaic (CPV) receivers and associated modules. Each CPV receiver may include a solar receiver having a light-receiving surface area of about 4 mm² or less, as well as concentrating optical elements, associated support structures, and conductive structures/terminals for electrical connection to a backplane or other common substrate. The concentrating optics may include a secondary lens element (for example, placed or otherwise positioned on or adjacent to the light receiving surface of the solar cell), and a primary lens element (for example, a Fresnel lens, a plano-convex lens, a double-convex lens, a crossed panoptic lens, and/or arrays thereof) that may be positioned over the secondary lens element to direct incident light thereto.

As described herein, a solar receiver includes two or more electrically independent photovoltaic cells (also referred to herein as solar cells) that are stacked, for example, vertically. The vertically stacked cells can be fabricated using transfer-printing processes, similar to those described, for example, in U.S. Pat. No. 7,972,875 to Rogers et al. entitled “Optical Systems Fabricated By Printing-Based Assembly,” the disclosure of which is incorporated by reference herein in its entirety. The individual solar cells (also referred to herein as ‘subcells’ with respect to the solar receiver) can be designed or otherwise configured to increase or maximize the capture of light from the terrestrial solar spectrum. In particular, embodiments of the present invention provide methods and structures for fabricating inter-cell interfaces that reduce Fabry-Perot cavity light loss and/or provide high dielectric strength between the electrically isolated subcells.

Some previous attempts at making mechanically stacked solar cells may suffer from optical loss arising from a Fabry-Perot cavity, which may be formed at interfaces between the stacked high refractive index semiconductors. As described in greater detail below, embodiments of the invention include fabrication methods and/or other strategies which can be used to form a highly transparent, low-loss optical interface between the individual subcells, using a multi-layer dielectric stack including dielectric layers having different refractive indices. Also, embodiments of the invention include methods and/or other strategies for extraction of electrical current from the lower subcell in a stacked configuration.

Accordingly, some embodiments of the present invention can provide solar receivers that are not constrained by the current-matching limitation associated with monolithically grown multi junction solar cells (where the cells are electrically connected in a serial manner), and/or solar receivers that do not require light-blocking metallic structures to conduct current out of the solar cell.

FIG. 1 illustrates a solar receiver 100 including vertically stacked electrically independent subcells according to some embodiments of the present invention. Referring now to FIG. 1, at least two electrically independent or isolated subcells 105, 110 are included as layers of a vertically-stacked structure 100, where the dashed lines 115 represent the bond interfaces between transferred layers (which may be transferred, for example, by transfer-printing). The bond interface 115 may include a discrete bonding layer, or may be provided by other bonding technologies that do not use discrete bonding layers. The subcells 105, 110 can be stacked, for example, using direct transfer-printing, where one or more of the subcells 105, 110 may be transferred to the illustrated substrate 120 (which may be a non-native or carrier substrate) from different substrates (for example, one or more growth substrates). A low optical loss interface 101, described in greater detail below, is provided between the upper 110 and lower 105 subcells, and may provide electrical isolation therebetween. In the embodiment of FIG. 1, each subcell 105, 110 in the vertical stack 100 also includes two conductive terminals 105a/b, 110a/b to electrically connect the subcells 105, 110 of the solar receiver 100 to other photovoltaic cells and/or a backplane; however, it will be understood that some embodiments may include subcells having fewer or more terminals, and/or subcells having a different number of terminals in a same stack.

FIG. 2 illustrates the low optical loss interface 101 according to some embodiments of the present invention in greater detail. In particular, FIG. 2 illustrates a multi-layer stack 101 including dielectric layers or films 102, 103, 104 having different refractive indices, which are configured to reduce or minimize optical losses in one or more wavelength ranges. The dashed line 115 represents the bond interface between transferred layers. The stack illustrated in FIG. 2 may be formed as follows. A high refractive index dielectric layer 102 is deposited on a lower subcell 105, in particular, onto the top-most semiconductor layer 125 (also having a high refractive index) of the lower subcell 105. The high refractive index semiconductor layer 125 can be a window layer or a lateral conduction layer. A lower refractive index dielectric layer 103 is deposited on the high refractive index dielectric layer 102. The lower refractive index dielectric layer 103 can have an appreciable thickness, and is configured to increase the dielectric strength of the interface layer stack 101. Another high refractive index dielectric layer 104 is deposited on the lower refractive index dielectric layer 103, and the upper subcell 110 can be printed onto the high refractive index dielectric layer 104, such that a bottom-most semiconductor layer 130 (also having a high refractive index) of the upper subcell 110 defines the bond interface 115 with the high refractive index dielectric layer 104.

As such, a high refractive index semiconductor layer 130 of the upper subcell 110 is provided on the high refractive index dielectric layer 104 (as shown by the dashed line 115 in FIG. 2), and is separated from the high refractive index semiconductor layer 125 of the lower subcell 105 by the multi-layer dielectric stack 101. The multi-layer dielectric stack 101 may thus provide a highly transparent, low-loss optical interface between the upper and lower sub-cells 110 and 105. In addition, the multi-layer dielectric stack 101 can provide an interface having good dielectric strength, which can withstand tens of volts without electrical loss or breakdown. As such, ultra-thin dielectrics may be of limited use in the multi-layer dielectric stack 101.

FIG. 3 is a graph illustrating optical transmission through an optical interface provided by a multi-layer dielectric stack according to some embodiments of the present invention. In particular, FIG. 3 illustrates wavelength vs. transmittance through a dielectric stack including a 125 nanometer (nm)-thick titanium oxide (TiOₓ) high refractive index layer, a 1 μm-thick silicon dioxide (SiO₂) lower refractive index layer, and another 125 nm-thick TiOₓ high refractive index layer (e.g., a TiOₓ/SiO₂/TiOₓ stack) between two gallium arsenide (GaAs) substrates. As shown in FIG. 3, the multi-layer dielectric stack is highly transparent and thus shows good transmission in the illustrated wavelength range (e.g., over a 300 nm to 1800 nm wavelength range). Also, the use of the lower refractive index, 1 micron-thick silicon dioxide layer (sandwiched between the higher refractive index, 125 nm-thick TiOₓ layers) provides excellent dielectric strength.

FIGS. 4A-4D illustrate fabrication steps that may be used for forming solar receivers including vertically stacked subcells according to embodiments of the present invention using one or more transfer-printing processes. In particular, FIG. 4A illustrates fabrication of a printable lower subcell 405 including lateral conduction layers 425, 435 and a low optical loss interface 401, as provided by the multi-layer dielectric stack according to embodiments of the present invention. For example, in FIG. 4A, the lower subcell 405 may include one or more layers 435, 405, 425 that are eptiaxially grown on a native substrate 495, and the multi-layer dielectric stack may be formed on the lower subcell 405 in a manner similar to that described above with reference to FIG. 2 to define the low optical loss interface 401. FIG. 4B illustrates fabrication of a printable upper subcell 410 in a separate and/or parallel process. For example, in FIG. 4B, the upper subcell 410 may include one or more layers 430, 410 that are eptiaxially grown on a native substrate 490 separate from that of the lower subcell 405. FIG. 4C illustrates transfer-printing of the lower subcell 405 and layers 435, 425, and 401 onto a non-native substrate 420, and FIG. 4D illustrates transfer-printing of upper subcell 410 including layer 430 onto lower subcell 405. In sonic embodiments, the upper and lower subcells 410, 405 grown on separate source substrates 490, 495 may have differing bandgaps, such that embodiments of the invention can allow for heterogeneous integration of high bandgap multi-junction solar cells (such as InGaP/GaAs) on low bandgap multi junction solar cells (such as InGaAsP/InGaAs), which may also be referred to as a tandem solar cell structure.

FIG. 5 illustrates a four-terminal solar receiver 500 according to some embodiments of the present invention. The example of FIG. 5 illustrates a InGaP 510n, 510p/GaAs 510n′, 510p′ two-junction subcell 510 stacked onto a InGaAsP 505n, 505p/InGaAs 505n′, 505p′two-junction subcell 505, with tunnel junction layers 510t therebetween. In FIG. 5, the lateral conduction layer 530 that serves as the anode connection 510b (terminal 2) to the top/upper subcell 510 is GaAs, and the cathode connection 510a (terminal 1) to the upper subcell 510 is provided by a n+ GaAs cap layer 511. The multi-layer dielectric stack 502, 503, 504 (which provides a low optical loss interface 501) is provided between the GaAs lateral conduction 530 layer that serves as the anode connection 510b (terminal 2) to the upper subcell 510 and the lateral conduction layer 525 that serves as the cathode connection 505a (terminal 3) for the bottom/lower subcell 505. The lateral conduction layer 525 that provides the cathode connection 505a (terminal 3) to the lower subcell 505 may be InP or InAlGaAs. The lateral conduction layer 535 that serves the anode connection 505b (terminal 4) for the lower subcell 505 may, for example, be InP or InGaAs.

In the embodiment of FIG. 5, the lower subcell 505 does not use a metallic grid structure for the cathode connection 505a, but instead, uses a doped semiconductor layer 525 having a bandgap larger than the underlying p-n junctions 505n/p, 505n′/p′. This can be possible due to the relatively small size (e.g., less than about 2 mm) of the subcells 505, 510. However, metallic lines/grid features 523 may be etched or otherwise formed in or on the topmost semiconductor layer 540 of the upper subcell 510 and covered with an anti-reflection coating (ARC) 512, which may be formed on a window layer 510w, such as InAlP.

FIG. 6 illustrates a four-terminal solar receiver 600 according to further embodiments of the present invention. The embodiment of FIG. 6 includes a InGaP 610n, 610p/GaAs 610n′, 610p′ two junction subcell 610 stacked onto a InGaAsP 605n, 605p/InGaAs 605n′, 605p′ two junction subcell 605 with tunnel junction layers 610t therebetween similar to the embodiment of FIG. 5, but includes buried grid technology for the cathode connection 605a (terminal 3) of the lower subcell 605. More particularly, in FIG. 6, the lower subcell 605 includes a recessed metallic grid 613 to extract electrical current, which may be formed as follows. Features 614 are etched into a topmost semiconductor layer 625 that provides the cathode connection 605a (terminal 3) of the lower subcell 605, where layer 625 has a bandgap larger than the underlying p-n junctions 605n/p, 605n′/p′. A lift-off metallization process is used to form metal lines 613l that define the grid 613 within the etched features 614 in the topmost semiconductor layer 625. The thickness of the metal is selected such that the surface of the metal resides below the upper surface of the semiconductor layer 625. The multi-layer dielectric stack 602, 603, 604, which provides the low optical loss interface 601 described herein, is deposited on the topmost semiconductor layer 625 of the lower subcell 605 including the metal lines 613l therein. One or more of the dielectric layers 602, 603, 604 of the multi-layer stack may conform to the etched features 614 and/or the metal lines 613l therein in some embodiments.

Still referring to FIG. 6, the upper subcell 610 is printed onto the multi-layer dielectric stack 602, 603, 604 on the lower subcell 605. The lateral conduction layer 630 that serves as the anode connection 610b (terminal 2) to the upper subcell 610 is GaAs, and the cathode connection 610a (terminal 1) to the upper subcell 610 is provided by a n+ GaAs cap layer 611. The lateral conduction layer 635 that serves the anode connection 605b (terminal 4) for the lower subcell 605 may, for example, be InGaAs. As further shown in FIG. 6, metallic lines/grid features 623 may also be etched or otherwise formed in or on the topmost semiconductor layer 640 of the upper subcell 610 and covered with an anti-reflection coating (ARC) 612, which may be formed on an InAlP window layer 610w. In some embodiments, the grid features 623 on the upper subcell 610 may overlay or otherwise be aligned with the grid features 613 on the bottom subcell 605 to reduce or minimize shadowing loss from the grid features 613, 623.

FIG. 7 illustrates a four-terminal solar receiver 700 according to some embodiments of the present invention. The example of FIG. 7 illustrates a triple junction upper subcell 710 vertically stacked onto a single-junction Ge cell 705. In particular, the upper subcell 710 includes three-junctions (InGaP 710p, 710n/GaAs 710p′, 710n′/InGaNAsSb 710p″, 710n″) with tunnel junction layers 710t therebetween, and is transfer printed onto a TiOₓ/SiO₂/TiOₓ or other multi-layer dielectric stack 702, 703, 704 on a Ge lower subcell 705. In FIG. 7, the lateral conduction layer 730 that serves as the anode connection 710b (terminal 2) to the upper subcell 710 is GaAs, and the cathode connection 710a (terminal 1) to the upper subcell 710 is provided by a n+GaAs cap layer 711. The multi-layer dielectric layer 702, 703, 704 (which provides the low optical loss interface 701) is provided between the GaAs lateral conduction layer 730 that provides the anode connection 710b (terminal 2) to the upper subcell 710 and the InGaAs layer 725 that serves as the cathode connection 705a (terminal 3) for the lower subcell 705. The anode connection 705b (terminal 4) to the lower subcell 705 is provided by a contact 721 on a surface of the Ge lower subcell 705. Metallic lines/grid features 723 may also be etched or otherwise formed in or on the topmost semiconductor layer 740 of the upper subcell 710 and covered with an anti-reflection coating (ARC) 712, which may be formed on an InAlP window layer 710w.

FIG. 8 illustrates a two-terminal stacked solar receiver 800 according to some embodiments of the present invention. The example of FIG. 8 may be formed by electrically connecting two subcells 805, 810 in series. The example of FIG. 8 illustrates a InGaP 810n, 810p/GaAs 810n′, 810p′ two-junction subcell 810 stacked onto a InGaAsP 805n, 805p/InGaAs 805n′, 805p′two-junction subcell 805, with tunnel junction layers 810t therebetween. In FIG. 8, the multi-layer dielectric stack (which provides the low optical loss interface in some embodiments) is not included, as the subcells 805, 810 are not electrically isolated. The embodiment of FIG. 8 does not require the bond interface 815 between the subcells to carry current. An electrical connect is made off cell, but can still be performed as a wafer-level process.

As shown in FIG. 8, the bond interface 815 between the two subcells 810, 805 occurs between two lateral conduction layers GaAs 830 and InP 825 having different lattice constants. An electrical connection is provided between the layers 830, 825 by a metal jumper or conductor 809 between terminals 810b, 805a. As the upper subcell 810 is smaller than the underlying lower subcell 805, the electrical Interconnect 809 is provided at edges of the subcells 810, 805. The lateral conduction layer 835 that serves the anode connection 805b (terminal 2) for the lower subcell 805 may, for example, be InGaAs, while the cathode connection 810a (terminal 1) to the upper subcell 810 is provided by layer 811. Metallic lines/grid features 823 may be etched or otherwise formed in or on the topmost semiconductor layer 840 of the upper subcell 810 and covered with an anti-reflection coating (ARC) 812, which may be formed on a window layer 810w, such as InAlP.

In some embodiments, such as the embodiment of FIG. 8, the two subcells 805, 810 may generate substantially similar currents under the intended spectra of operation. In some embodiments, such as the embodiment of FIG. 8, one or more of the subcells 805, 810 may include more than two junctions to facilitate substantially matching the currents generated by each subcell. In some embodiments, the upper subcell 810 may be a triple junction cell including an InAlGaP junction, an AlGaAs junction, and a GaAs junction.

FIG. 9 illustrates a surface-mountable four-terminal solar receiver 900 according to some embodiments of the present invention. The solar receiver 900 includes two subcells 905, 910 separated by a multi-layer dielectric stack that provides a low optical loss interface 901 therebetween, similar to the embodiments described above. Lateral conduction layers 930, 925, 935 and bond interfaces 915 may also be provided as shown. In FIG. 9, each cell-level terminal 910a/b, 905a/b is electrically connected to a designated substrate-level connection pad 987 by wirebonds 985. The substrate 920 includes thru-substrate interconnects 981, and the backside pads 987 are configured for mounting to solar module backplanes.

FIGS. 10A-10B illustrate front and back views 1000a and 1000b, respectively, of a surface-mountable four-terminal solar receiver according to some embodiments of the present invention. In FIGS. 10A-10B, the electrical connections 1085 between the cell-level contacts and the substrate-level contacts 1088 are formed using thin-film metallization processes. The substrate 1020 includes thru-hole interconnects 1081, and the backside pads 1087.

FIGS. 11 and 12 illustrate example matching networks for use with some embodiments of the present invention. In particular, FIG. 11 illustrates a voltage matching network 1100 that may be used with solar receivers according to some embodiments of the present invention, while FIG. 12 illustrates a current matching network 1200 that may be used with solar receivers according to some embodiments of the present invention.

FIG. 13 illustrates a solar receiver 1300 including a two-subcell stack 40, 20 on a substrate 1320 according to some embodiments of the present invention. As shown in FIG. 13, the lower subcell 20 includes metal lines 1313l, that define a grid 1313 within the etched features 1314. The embodiment of FIG. 13 may be fabricated in accordance with some methods described in commonly assigned U.S. patent application Ser. No. 13/352,867 to Menard et at entitled “Laser Assisted Transfer Welding Process,” filed Jan. 18, 2012, the disclosure of which is incorporated by reference herein in its entirety.

FIG. 14 is an optical microscope image illustrating a solar receiver 1400 according to some embodiments of the present invention. In particular, FIG. 14 illustrates a triple junction solar cell 1410 directly printed on an underlying single junction InGaAs solar cell 1405. The triple junction subcell 1410 may be separated from the single junction subcell 1405 by a multi-layer dielectric stack that provides a low optical loss interface therebetween, similar to the embodiments described above. The single junction InGaAs solar cell 1405 may have a lower bandgap than the triple junction subcell 1410 thereon, and may include a recessed grid structure in some embodiments.

In some embodiments, one or more CPV modules according to embodiments of the present invention can be mounted on a support for use with a multi-axis tracking system. The tracking system may be controllable in one or more directions or axes to align the CPV receivers with incident light at a normal (e.g., on-axis) angle to increase efficiency. In other words, the tracking system may be used to position the CPV modules such that incident light (for example, sunlight) is substantially parallel to an optical axis of the optical element(s) that focus the incident light onto the CPV receivers. In an alternative arrangement, the CPV modules can have a fixed location and/or orientation.

The present invention has been described above with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. In no event, however, should “on” or “directly on” be construed as requiring a layer to cover an underlying layer.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entireties.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments of the present invention described herein, and of the manner and process of making and using them, and shall support claims to any such combination or subcombination.

In the specification, there have been disclosed embodiments of the invention and, although specific terms are employed, they are used in a generic and descriptive sense only and not for purposes of limitation, the scope of the present invention being set forth in the following claims.

1. (canceled)

2. A solar receiver, comprising:
a first photovoltaic cell;
a second photovoltaic cell on the first photovoltaic cell and electrically independent therefrom; and
a multi-layer dielectric stack between the first and second photovoltaic cells, the multi-layer dielectric stack comprising at least two dielectric layers having different refractive indices.

3. The solar receiver of claim 2, wherein the multi-layer dielectric stack comprises:
a first dielectric layer;
an intermediate dielectric layer on and having a lower refractive index than the first dielectric layer; and
a second dielectric layer on and having a higher refractive index than the intermediate dielectric layer.

4. The solar receiver of claim 3, wherein the multi-layer dielectric stack defines an interface between a semiconductor layer of the first photovoltaic cell having a higher refractive index than the first dielectric layer and a semiconductor layer of the second photovoltaic cell having a higher refractive index than the second dielectric layer.

5. The solar receiver of claim 4, wherein the first and second photovoltaic cells comprise respective semiconductor materials having different lattice constants.

6. The solar receiver of claim 2, wherein the first and/or second photovoltaic cells respectively include at least two conductive terminals.

7. The solar receiver of claim 2, wherein the first and/or second photovoltaic cells are single-junction or multi junction photovoltaic cells.

8. A solar receiver, comprising:
a first photovoltaic cell;
a second photovoltaic cell on the first photovoltaic cell and electrically connected in series therewith, the first and second photovoltaic cells comprising respective semiconductor materials having different lattice constants, wherein a bond interface between the first and second photovoltaic cells occurs between the respective semiconductor materials.

9-10. (canceled)

11. The solar receiver of claim 8, wherein electrical current passes directly through the bond interface.

12. The solar receiver of claim 11, wherein the solar receiver has a light receiving area of less than about 4 square millimeters.

13. The solar receiver of claim 8, wherein the bond interface between the first and second photovoltaic cells is a poor electrical conductor.

14. The solar receiver of claim 13, wherein the bond interface between the first and second photovoltaic cell comprises:
a first electrically conducting layer at a top of the first photovoltaic cell;
a second electrically conducting layer at a base of the second photovoltaic cell, and further comprising:
an electrical connection between the first and second electrically conducting layers.

15. The solar receiver of claim 14, wherein the second electrically conducting layer at the base of the second photovoltaic cell comprises a doped semiconductor that is lattice matched with the second photovoltaic cell and has a bandgap larger than a bandgap of the first photovoltaic cell.

16. The solar receiver of claim 15, wherein the first electrically conducting layer at the top of the first photovoltaic cell comprises a doped semiconductor that is lattice matched with the first photovoltaic cell and has a bandgap larger than the bandgap of the first photovoltaic cell.

17-18. (canceled)

19. The solar receiver of claim 14, wherein the electrical connection between the first and second electrically conductive layers comprises a metal conductor extending outside of an active area of the first and second photovoltaic cells.

20-21. (canceled)

22. The solar receiver of claim 3, wherein a thickness and a dielectric strength of the intermediate dielectric layer are greater than those of the first and second dielectric layers.

23. The solar receiver of claim 22, wherein the first and second dielectric layers comprise metal oxides, and wherein the intermediate dielectric layer comprises a silicon oxide or nitride.

24. The solar receiver of claim 5, wherein one of the first and second photovoltaic cells comprises a high bandgap semiconductor material, and wherein another of the first and second photovoltaic cells comprises a low bandgap semiconductor material.

25. The solar receiver of claim 24, wherein the first and/or second photovoltaic cells are transfer-printed cells having a bond interface between the semiconductor layer of the second photovoltaic cell and the second dielectric layer of the multi-layer dielectric stack.

26. A method of fabricating a solar receiver, the method comprising:
forming a multi-layer dielectric stack on a first photovoltaic cell, the multi-layer dielectric stack comprising at least two dielectric layers having different refractive indices; and
stacking a second photovoltaic cell on the multi-layer dielectric stack, wherein the second photovoltaic cell is electrically independent from the first photovoltaic cell.

27. The method of claim 26, wherein forming the multi-layer dielectric stack comprises:
forming a first dielectric layer on the first photovoltaic cell;
forming an intermediate dielectric layer having a lower refractive index than the first dielectric layer thereon; and
forming a second dielectric layer having a higher refractive index than the intermediate dielectric layer thereon,
wherein the second photovoltaic cell is stacked on the second dielectric layer.

28. The method of claim 27, wherein the multi-layer dielectric stack defines an interface between a semiconductor layer of the first photovoltaic cell having a higher refractive index than the first dielectric layer and a semiconductor layer of the second photovoltaic cell having a higher refractive index than the second dielectric layer.

29. The method of claim 28, wherein the first and second photovoltaic cells comprise respective semiconductor materials having different lattice constants, and further comprising:
epitaxially growing one or more layers of the first photovoltaic cell on a first source substrate;
epitaxially growing one or more layers of the second photovoltaic cell on a second source substrate different than the first source substrate,
wherein stacking the second photovoltaic cell comprises:
transferring the second photovoltaic cell from the second source substrate onto the second dielectric layer of the multi-layer dielectric stack using a transfer-printing process.
